(19) United States
(12) Patent Application Publication
(10) Pub. No.: US 2009/0323414 A1
(43) Pub. Date: Dec. 31, 2009

(54) Method and Device for Storing Data

(76) Inventors: Heiko Fibranz, Muenchen (DE); Paul Schmoelz, Muenchen (DE)

Correspondence Address: SLATER & MATSIL, L.L.P., 17950 PRESTON ROAD, SUITE 1000, DALLAS, TX, 75252, US

(21) Appl. No.: 12/164,251

(22) Filed: Jun. 30, 2008

(51) Int. Cl. G11C 16/04; G11C 7/00; G11C 11/00

(52) U.S. Cl. 365/185.03; 365/185.18; 365/148; 365/189.011

(57) ABSTRACT

In one aspect a method of storing data in an integrated circuit may include identifying a group of storage sites from a plurality of storage sites; selecting a plurality of storage levels, each storage level being assignable to a storage site in the group of storage sites; and assigning a unique storage level to each of the storage sites in the group of storage sites, each unique storage level assigned from the plurality of storage levels.

### TECHNICAL FIELD

This description is directed to a method and a device for storing data.

### BRIEF DESCRIPTION OF THE DRAWINGS

Details of one or more implementations are set forth in the accompanying drawings and description below. Other features will be apparent from the description and drawings, and from the claims.

FIG. 1 shows a flow diagram illustrating a method of encoding data, according to one example;

FIG. 2 shows a flow diagram illustrating a method of decoding data, according to a further example;

FIGS. 3A and 3B show examples of multi-level memory cells;

FIG. 4 shows examples of current-voltage characteristics for different threshold voltages of a memory cell;

FIGS. 5A and 5B show distributions of threshold voltages for a single four-level memory cell (FIG. 5A) and a plurality of four-level memory cells (FIG. 5B) in an integrated circuit, according to a further example;

FIGS. 6A and 6B show distributions of the threshold voltages for a single eight-level memory cell (FIG. 6A) and a plurality of eight-level memory cells (FIG. 6B) in an integrated circuit, according to another example;

FIG. 7 shows a schematic of an integrated circuit, according to yet another example, having at least one memory unit that has a plurality of memory cells;

FIG. 8 shows an example of a reading process;

FIGS. 9A and 9B show schematic circuit diagrams for cell arrays in memory devices, according to further examples of integrated circuits;

FIG. 10 shows an example of an electronic device;

FIG. 11A shows a schematic cross section of a conductive bridging memory, according to yet another example of an integrated circuit;

FIG. 11B shows an example of different storage levels according to a memory of FIG. 11A;

FIG. 12A shows a schematic cross section of a phase change memory, according to yet another example of an integrated circuit; and

FIG. 12B shows a resistance distribution for an array of cells according to the example of FIG. 12A.

### DETAILED DESCRIPTION OF ILLUSTRATIVE EMBODIMENTS

In one aspect, a high storage density of memory devices may be achieved by large scale integration of memory cells or with a high density of memory cells on a chip. In another aspect, a high capability for a single cell may be provided, i.e., a single cell may be provided with the capability to store a large amount of information therein. For example, a memory cell may store information of two bits. In a further aspect, encoding and decoding may make use of an increased capability for a single memory cell.

In one aspect a method of encoding data may include receiving an input set of data; and generating an output set of data depending on the received input set, the output set having a plurality of output signals each representing a specific signal level that is unique within the plurality of output signals included in the output set. The output set of data may be generated depending on the received input set in such a way that, independent of the received input set, each specific signal level represented by one of the output signals is unique within the plurality of output signals included in the output set. The output set may be generated depending on the received input set in accordance with a bijective mapping between input sets and output sets.

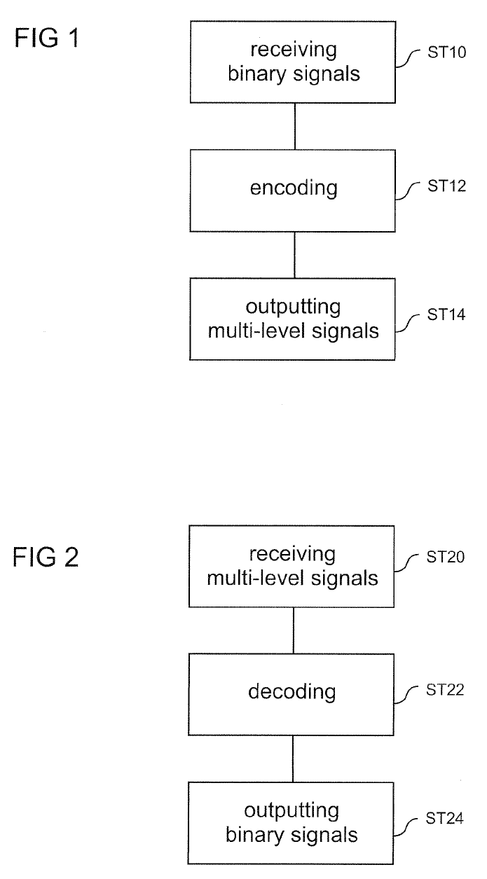

FIG. 1 shows a flow diagram according to one example of a method of encoding data, where in a first step ST10 a set of binary signals is received. In a second step ST12, the received binary data are encoded and a set of multi-level data is generated depending on the received input set of binary data. In a third step ST14, the encoded data are output in the form of generated multi-level signals.

In one aspect the input set of binary data has a plurality of binary data or binary signals or binary signal components, where each signal component may represent one bit of information, for example. Each binary signal or signal component, therefore, takes one out of two possible signal levels which may be called, for example, “high” and “low”, or “0” and “1”, respectively. The input set of binary data may be received in parallel, i.e., more than one binary signal may be received at the same time. In another aspect more than one binary signal of the input set of binary signals may be received serially, i.e., in succession.

The output set of multi-level data may have a plurality of multi-level signals or multi-level signal components, wherein each signal component takes one out of a plurality of possible signal levels such that each taken signal level occurs not more than once within the output set, i.e., for each of the plurality of possible signal levels not more than one signal component within the output set actually takes the signal level. In one aspect the number of possible signal levels is not smaller than the number of signal components within the output set. Accordingly, in one example the output set may have a number of n output signals or signal components, wherein each signal component takes one out of a number of k possible signal levels, wherein k≧n.

In one aspect the output set has more than 2 output signals, such as 3 output signals, for example. In another example the output set has 4 multi-level output signals, wherein each output signal component takes one out of at least 4 possible signal levels, for example. In another example the output set may have 8 multi-level output signals, wherein each output signal component takes one out of at least 8 possible signal levels, for example. Nevertheless, the method is not limited to these numbers of output signal components or to the number of possible signal levels. It will be appreciated that any other number of output signals may be included in the output set and that any other number of possible signal levels that is not smaller than the number of output signal components within the output set may be applied.

Accordingly, the output set of multi-level data is generated depending on the received input set such that each signal level is unique within the output set regardless of the input set, i.e., for any received input set the method ensures that each signal level within the output set appears not more than once. While the input set of binary data may have two or more signals having the same signal level, all of the signals within the output set of multi-level signals have different signal levels. Therefore, the relative levels or the order or sequence of the levels of the output signals with respect to each other may identify the encoded data that are generated based on the received input set of binary data.

In another aspect, it is not required that each signal level represented by one of the output signals is unique within the plurality of output signals included in the output set. Instead, one or more of the signals levels may be represented by two or more output signals within the same output set. In this aspect, it may be defined for each signal level how many output signals within the output set are to be set to the signal level, i.e., each signal level may be represented or occupied by a predefined number of output signals within the output set. In one aspect, this number may be called an occupation number or occurrence number of the respective signal level.

Accordingly, a method of encoding may include identifying or selecting a plurality of signal levels; defining for each signal level from the plurality of signal levels how many output signals within an output set are to be set to the signal level, i.e., defining an occupation number for each signal level; receiving an input set of data, such as binary data, for example; and generating the output set of data depending on the received input set in such a way that, independent of the received input set, each specific signal level within the plurality of signal levels is represented by as many output signals within the output set as define by the predetermined occurrence number of the respective signal level. Accordingly, the number of output signals within the output set may be identical to the sum of the selected signal levels multiplied by the respective occurrence number. In one aspect, the occurrence numbers for all signal levels within the plurality of signal levels may be the same. In another aspect, one or more signal levels may have a different occurrence number than other signal levels. In the specific case, where the occurrence number of all signal levels within the plurality of signal levels is 1, each signal level is unique within the output set as in the example described above.

In one example the output set is generated such as to biuniquely represent the input set, i.e., a biunique relation between the received input set of binary data and the generated output set of multi-level data exists. Accordingly, for each combination of received binary signals, i.e., for each combination of “0”s and “1”s, one uniquely defined combination of output signals is generated.

Such a biunique relation may be defined or described by means of a mathematical function or assignment rules that biuniquely assign to each input set one particular output set. Moreover, for different input sets also different output sets are generated, in accordance with this aspect of a biunique assignment.

In another example the biunique relation may be defined or described by means of an encoding table. Table 1 shows an example of an encoding table that may be applied in a case where both the input set and the output set each has four signal components. Each line in the left column of Table 1 represents one input set of binary data (four bits) and the corresponding line in the right column represents the corresponding output set of multi-level data or multi-level signals. The input set has four binary data or four bits denoted with B₃, B₂, B₁, and B₀, each taking one out of two possible signal levels denoted with “0” and “1”. The four signal components included in the output set of multi-level signals are denoted with C₄, C₃, C₂, and C₁, wherein depending on the received binary data each signal component of the output set takes one out of four possible signal levels such as voltage signals denoted with “V₄”, “V₃”, “V₂”, and “V₁”, respectively, where all voltage signals V₁ to V₄ are different from each other, for example.

In accordance with the example of Table 1, when receiving an input set of binary data represented by the bit sequence 0-0-0-0, the method generates an output set of multi-level data where the signal components C₁, C₂, C₃, and C₄ take the signal levels “V₁”, “V₂”, “V₃”, and “V₄”, respectively. As a further example, when receiving the bit sequence 0-1-0-1, the method in accordance with Table 1 generates an output set of multi-level data, where the signal components C₁, C₂, C₃, and C₄ take the signal levels “V₃”, “V₄”, “V₂”, and “V₁”, respectively. As can be seen from Table 1, for all output sets none of the signal levels occurs more than once within the same output set of multi-level signals. Accordingly, the signal levels of the output signals are generated such that a generated ordering of the signal components C₁ to C₄ according to their relative signal level uniquely identifies or represents the input set of binary data. Accordingly, a comparison of absolute values of the signal levels with an external reference value is not required.

TABLE 1
Example of an encoding/decoding table for 4 cells

| | |
|---|---|
| | V_{T} level in |
| Data bit | cell |

| B₃ | B₂ | B₁ | B₀ | C₄ | C₃ | C₂ | C₁ |
|---|---|---|---|---|---|---|---|
| 0 | 0 | 0 | 0 | V₄ | V₃ | V₂ | V₁ |
| 0 | 0 | 0 | 1 | V₄ | V₃ | V₁ | V₂ |
| 0 | 0 | 1 | 0 | V₄ | V₁ | V₃ | V₂ |
| 0 | 0 | 1 | 1 | V₁ | V₄ | V₃ | V₂ |
| 0 | 1 | 0 | 0 | V₁ | V₄ | V₂ | V₃ |
| 0 | 1 | 0 | 1 | V₁ | V₂ | V₄ | V₃ |
| 0 | 1 | 1 | 0 | V₁ | V₂ | V₃ | V₄ |
| 0 | 1 | 1 | 1 | V₁ | V₃ | V₄ | V₂ |
| 1 | 0 | 0 | 0 | V₃ | V₄ | V₁ | V₂ |
| 1 | 0 | 0 | 1 | V₃ | V₁ | V₂ | V₄ |
| 1 | 0 | 1 | 0 | V₃ | V₂ | V₄ | V₁ |
| 1 | 0 | 1 | 1 | V₂ | V₄ | V₃ | V₁ |
| 1 | 1 | 0 | 0 | V₂ | V₃ | V₁ | V₄ |
| 1 | 1 | 0 | 1 | V₂ | V₁ | V₄ | V₃ |
| 1 | 1 | 1 | 0 | V₂ | V₄ | V₃ | V₁ |
| 1 | 1 | 1 | 1 | V₂ | V₄ | V₁ | V₃ |

As can be seen from Table 1, it is not required that each possible combination of output signals is actually assigned to one of the possible input sets. For example, in Table 1, the signal level sequence V₁-V₃-V₂-V₄ is not used in this example of an encoding table.

In another example shown in Table 2 the input set has six binary data or six bits denoted with B₅, B₄, B₃, B₂, B₁, and B₀, each taking one out of two possible signal levels denoted with “0” and “1”. The six signal components included in the output set of multi-level signals are denoted with C₆, C₅, C₄, C₃, C₂, and C₁, wherein depending on the received binary data each signal component of the output set takes one out of three possible signal levels such as the voltage signals denoted with “V₃”, “V₂”, and “V₁” in the shown example, respectively, where all voltage signals V₁ to V₃ are different from each other. According to this example, each signal level within the output set has an occurrence number of 2, i.e., each signal level occurs twice in the output set. Encoding and/or decoding, however, is not limited to a situation where each signal level occurs equally often. In another example not explicitly shown here, some signal levels may occur more often than other signal levels.

When receiving an input set of binary data represented by the bit sequence 0-0-0-0-0-0, the method generates an output set of multi-level data where the signal components C₁, C₂, C₃, C₄, C₅ and C₆ take the signal levels “V₁”, “V₁”, “V₂”, “V₂”, “V₃”, and “V₃”, respectively. As a further example, when receiving the bit sequence 0-0-1-0-1-0, the method in accordance with Table 2 generates an output set of multi-level data, where the signal components C₁, C₂, C₃, C₄, C₅, and C₆ take the signal levels “V₂”, “V₃”, “V₃”, “V₂”, “V₁”, and “V₁”, respectively. As can be seen from Table 2, for all output sets each of the signal levels occurs exactly twice within the same output set of multi-level signals. Accordingly, the signal levels of the output signals are generated such that a generated ordering of the signal components C₁ to C₆ according to their relative signal level uniquely identifies or represents the input set of binary data. Accordingly, a comparison of absolute values of the signal levels with an external reference value is not required.

TABLE 2
Example of an encoding/decoding table for 6 cells with three distinct
storage levels

| Data bit | | | | | | V_{T} level in cell | | | | | |
|---|---|---|---|---|---|---|---|---|---|---|---|
| B₅ | B₄ | B₃ | B₂ | B₁ | B₀ | C₆ | C₅ | C₄ | C₃ | C₂ | C₁ |
| 0 | 0 | 0 | 0 | 0 | 0 | V₃ | V₃ | V₂ | V₂ | V₁ | V₁ |
| 0 | 0 | 0 | 0 | 0 | 1 | V₃ | V₃ | V₂ | V₁ | V₂ | V₁ |
| 0 | 0 | 0 | 0 | 1 | 0 | V₃ | V₃ | V₁ | V₂ | V₂ | V₁ |
| 0 | 0 | 0 | 0 | 1 | 1 | V₃ | V₁ | V₃ | V₂ | V₂ | V₁ |
| 0 | 0 | 0 | 1 | 0 | 0 | V₁ | V₃ | V₃ | V₂ | V₂ | V₁ |
| 0 | 0 | 0 | 1 | 0 | 1 | V₁ | V₃ | V₃ | V₂ | V₁ | V₂ |
| 0 | 0 | 0 | 1 | 1 | 0 | V₁ | V₃ | V₃ | V₁ | V₂ | V₂ |
| 0 | 0 | 0 | 1 | 1 | 1 | V₁ | V₃ | V₁ | V₃ | V₂ | V₂ |
| 0 | 0 | 1 | 0 | 0 | 0 | V₁ | V₁ | V₃ | V₃ | V₂ | V₂ |
| 0 | 0 | 1 | 0 | 0 | 1 | V₁ | V₁ | V₃ | V₂ | V₃ | V₂ |
| 0 | 0 | 1 | 0 | 1 | 0 | V₁ | V₁ | V₂ | V₃ | V₃ | V₂ |
| 0 | 0 | 1 | 0 | 1 | 1 | V₁ | V₁ | V₂ | V₃ | V₂ | V₃ |
| 0 | 0 | 1 | 1 | 0 | 0 | V₁ | V₁ | V₂ | V₂ | V₃ | V₃ |
| 0 | 0 | 1 | 1 | 0 | 1 | V₁ | V₂ | V₁ | V₂ | V₃ | V₃ |
| 0 | 0 | 1 | 1 | 1 | 0 | V₂ | V₁ | V₁ | V₂ | V₃ | V₃ |
| 0 | 0 | 1 | 1 | 1 | 1 | V₂ | V₁ | V₂ | V₁ | V₃ | V₃ |
| 0 | 1 | 0 | 0 | 0 | 0 | V₂ | V₂ | V₁ | V₁ | V₃ | V₃ |
| 0 | 1 | 0 | 0 | 0 | 1 | V₂ | V₂ | V₁ | V₃ | V₁ | V₃ |
| 0 | 1 | 0 | 0 | 1 | 0 | V₂ | V₂ | V₃ | V₁ | V₁ | V₃ |
| 0 | 1 | 0 | 0 | 1 | 1 | V₂ | V₂ | V₃ | V₁ | V₃ | V₁ |
| 0 | 1 | 0 | 1 | 0 | 0 | V₂ | V₂ | V₃ | V₃ | V₁ | V₁ |
| 0 | 1 | 0 | 1 | 0 | 1 | V₂ | V₃ | V₂ | V₃ | V₁ | V₁ |

| | |
|---|---|
| etc. | etc. |

As can be seen from Table 2, it is not required that each possible combination of output signals is actually assigned to one of the possible input sets, since the number of possible input sets defined by 6 bits is 2⁶=64, while the number of possible combinations of output signals would amount to 90, in this example.

In one example, each signal level has a specific voltage level. The method, however, is not limited to this example where each signal level is represented by a particular level or value of an electrical voltage. In another example each signal level may be represented by a particular current level, i.e., a particular value of electrical current. In yet another example a particular amount of electrical charge may be provided as the signal level. This charge may be stored in a capacitive component, for example. Moreover, other characteristics of electrical or non-electrical signals, such as magnetic or optical properties, for example, may be applied in order to define or represent a multi-level signal. Depending on the specific implementation, the signal level may be represented by a relative or absolute value, a slope or a duration of the signal, for example.

In a further example generating the output set of multi-level data may include assigning to each output signal an ordinal number and setting the signal levels of the output signals in an ascending or descending order in accordance with the series of the assigned ordinal numbers. Referring to the encoding scheme shown in Table 1, the numbers 1 to 4 in the right column may represent such ordinal numbers, where each ordinal number may stand for a certain signal level, such as a voltage level, for example.

According to another example, the input set has a number of n binary signals and the output set has a number of k multi-level output signals such that depending on n, the number k is the smallest integer number the factorial k! of which is not smaller than 2ⁿ (k!≧2ⁿ).

In one aspect, the method of encoding data may be applied for encoding data to be stored in a group of storage sites of an integrated circuit. In one example, the integrated circuit may be a memory device and the group of storage sites may form a memory unit of the memory device. The memory unit may be formed by a plurality or a block of memory cells which may be addressed and/or read and/or written and/or accessed as one unit. In this aspect receiving the input set of binary data may include receiving binary signals on a data bus of the memory device. Furthermore, in this aspect the method may include transmitting each of the plurality of generated multi-level signals to one of a plurality or group of storage sites, such as multi-level memory cells, and setting the storage site, e.g., the multi-level memory cell, into one of a plurality of storage states depending on the generated and transmitted signal level. In one particular aspect, the input set may have a number of n binary signals and the group of storage sites may have a number of k storage sites or memory cells such that depending on n, the number k is the smallest integer number the factorial k! of which is not smaller than 2ⁿ.

In a further aspect a method of decoding data may include receiving an input set of multi-level data, the input set having a plurality of input signals each representing a specific signal level that is unique within the plurality of input signals included in the input set; and generating an output set of binary data depending on the received input set. In another example of a method of decoding, the input set may have a plurality of input signals each representing a specific signal level such that each signal level occurs within the input set as often as defined by a predetermined occurrence number assigned to the respective signal level.

FIG. 2 shows a flow diagram according to a method of decoding data, wherein in a first step ST20 a set of multi-level signals representing input data is received. In a second step ST22, the received input data are decoded and a set of binary signals representing output data is generated. In a third step ST24, the decoded data are output in form of the generated binary signals.

In one aspect of the method of decoding data the input set of multi-level data may be structured analogous to the output set of multi-level data according to a method of encoding data as described above. Furthermore, the output set of binary data according to one aspect of the method of decoding data may be structured analogous to the input set of binary data according to a method of encoding data as described above. Accordingly, in one aspect Table 1 or Table 2 may represent a decoding scheme or decoding table according to which one of the sets of binary data listed in the left column of Table 1 or Table 2 is output depending on which set of multi-level data listed in the right column is received.

In one example, generating the output set may include comparing signal levels of the input signals within the input set. According to this example, generating the output set may further include establishing a relative ordering of the input signals depending on their relative signal levels. Even further, the output set of binary data may be generated depending on the established ordering of the input signals.

According to another example, each input signal has a voltage signal. In one aspect the received multi-level signals and/or the generated binary signals have a voltage signal, where the respective signal level is represented by the value of the voltage signal.

In one aspect, the method of decoding data may be applied for decoding data stored in a group of storage sites of an integrated circuit. In one example, the integrated circuit may form a memory device and the group of storage sites may form a memory unit of the memory device having a plurality of multi-level memory cells. In this aspect receiving the input set of multi-level data may include determining the storage state for each of a plurality of multi-level memory cells and receiving one of a plurality of multi-level signal components for each of the plurality of multi-level memory cells the signal level of a signal component representing the storage state determined for the respective memory cell. Furthermore, in this aspect the method may include transmitting the generated output set of binary data to a data bus of the memory device.

A high storage density of memory devices may be achieved by utilizing a high capability for a single memory cell. For example, a memory cell may store information represented by more than one bit. Such memory cells may be regarded as multi-level memory cells, i.e., the memory cell may exhibit a plurality of different states that can be detected and distinguished from one another. These states, therefore, are regarded as storage states of the memory cell. In one aspect the different storage states may be defined and distinguished by different electrical properties of the cells. Nevertheless, the concept is not limited to cells defining the storage states by means of their electrical properties. In other examples other physical properties such as magnetic properties, optical properties, mechanical properties of the cells, etc. may be utilized to distinguish between different storage states. In one example a multi-level memory cell exhibits more than two storage states. In another example, a multi-level memory cell may exhibit more the four storage states. The larger the number of possible storage levels or storage states within the memory cell, the greater the amount of information that can be stored in the memory cell.

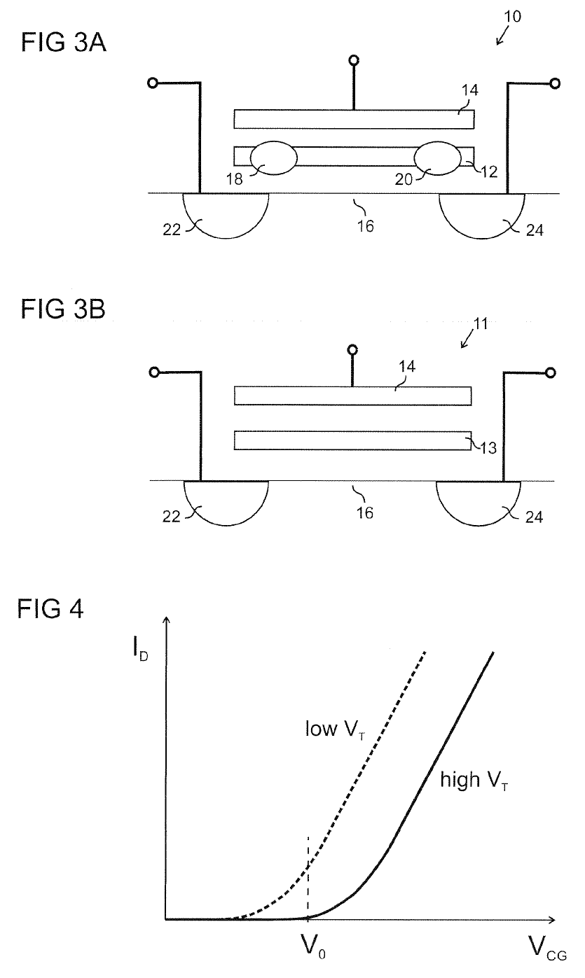

FIG. 3A shows a schematic example of an NROM-cell 10 that may take a plurality of different storage states, i.e. the memory cell may be a multi-level memory cell, for example. In particular, in the example of FIG. 3A the NROM-cell 10 may exhibit 4 different storage states.

The memory cell 10 may have a charge trapping layer 12 disposed between a control gate 14 and a channel region 16 of a field effect transistor (FET) structure, for example. The charge trapping layer 12 may have nitride material such as silicon nitride or other charge trapping material known in the art, for example. In the example shown in FIG. 3A the charge trapping layer 12 has a first localized charge trapping packet 18 and a second localized charge trapping packet 20. The first localized charge trapping packet 18 is disposed near a first end of the channel region 16 close to a source/drain contact 22 and the second localized charge trapping packet 20 is disposed near a second end of the channel region 16 close to a drain/source contact 24 of the FET structure. The memory cell, however, is not limited to the shown arrangement of the localized charge trapping packets near respective ends of the channel region 16. In another example, the first and/or the second and/or any further charge trapping packets may be disposed at any position between the first and second end position of the charge trapping layer 12.

Depending on the charge condition, i.e. the amount of electrical charge trapped in the first 18 and/or the second charge trapping packet 20, a certain threshold voltage V_{T} needs to be applied to the control gate 14 in order to switch on the channel region 16, i.e. in order to provide a sufficiently high conductance of the FET channel. Each of these charge conditions or storage conditions, therefore, is associated with a certain threshold voltage V_{T}. Accordingly, for a given gate voltage V_{CG} applied to the control gate and given source-drain voltage V_{SD} a channel current or drain current I_{D} depends on the storage state of the memory cell, i.e., the threshold voltage V_{T} associated with the storage state.

FIG. 4 demonstrates an example of a current voltage diagram, where the drain current I_{D} is plotted over the control gate voltage V_{CG} at a constant source-drain voltage for two different threshold voltages V_{T} corresponding to two different storage states. The dashed line represents an I-V-curve for a low threshold voltage V_{T}, i.e., a lower gate voltage V_{CG} is required for switching on the channel conductance. For a higher threshold voltage V_{T} (solid line) a higher gate voltage V_{CG} needs to be applied to the control gate in order to provide similar conductance of the transistor channel. Accordingly, in one example, the two storage states may be distinguished by determining the gate voltage V_{CG} that is needed for achieving a predetermined current in the transistor channel.

In another example, a constant gate voltage V_{CG} is applied and the resulting current I_{D} is detected. For example, when applying a voltage V₀ to the control gate, the drain current I_{D} is larger in a storage state represented by a low threshold voltage V_{T} (dashed line) as compared to a storage state represented by a high threshold voltage V_{T} (solid line). Therefore, determining the channel current or drain current I_{D} allows the evaluation of the storage state of the memory cell, i.e., a retrieval of the information stored in the memory cell. Accordingly, this evaluation may be regarded as a read operation of the memory cell.

In one aspect, each charge trapping packet shown in FIG. 3A exhibits two possible storage conditions, i.e., each charge trapping packet can be maintained in one of two possible states, either “programmed” or “erased”, represented by the presence or absence of trapped electrons, for example. In this aspect, each charge trapping packet represents one bit of information. Accordingly, the memory cell 10 according to the example of FIG. 3A enables the storage of two bit of information and, therefore, is regarded as a multi-level memory cell having four different storage states.

In another example, not shown in the figures, the charge trapping layer may have more than two charge trapping packets. These charge trapping packets may be disposed near end portions of the charge trapping layer, i.e., close to the source and drain contacts 22, 24, for example. In another example, not shown in the figures the charge trapping packets may be distributed over the full length of the charge trapping layer, i.e., the channel length, for example. In case of four charge trapping packets each charge trapping packet representing or storing one bit, for example, the memory cell is able to store 4 bits. Accordingly, in this example the memory cell may take one out of eight possible storage states each represented by one threshold voltage V_{T}, for example.

In yet another example, each charge trapping packet may take one of a plurality of charging states. For example, the charge trapping packets may exhibit more than two different charging states, i.e., depending on the amount of charge stored or trapped in a packet, one out of more than two states, or more than three states of even more than five or ten different states may be taken.

In another example, schematically shown in FIG. 3B, a multi-level memory cell 11 may have a floating gate 13 instead of the charge trapping layer 12 of FIG. 3A. This floating gate 13 may have electrically conductive material such that charging of the floating gate does not locally but uniformly change the potential of the floating gate 13. Depending on the amount of electrical charge on the floating gate 13 various levels of the electrical potential of the floating gate 13 may be achieved and, therefore, a plurality of storage levels can be obtained. Accordingly, such a floating gate transistor structure may serve as a multi-level memory cell.

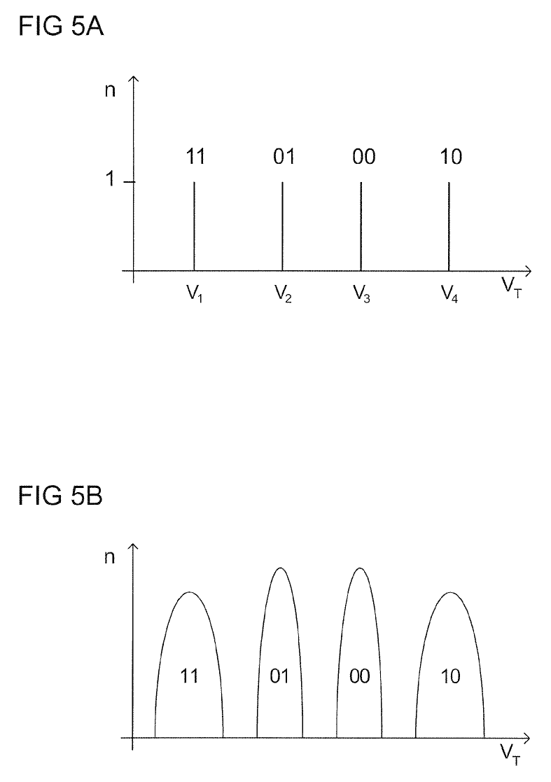

FIG. 5A demonstrates an example of a distribution of threshold voltage levels V_{T} for a memory cell that exhibits four possible storage states. The four storage states may be achieved by providing the memory cell with two bits each taking one of two possible conditions. Accordingly, in FIG. 5A the four storage levels are labeled with “11”, “01”, “00”, and “10” depending on the corresponding bit combinations, and the four storage levels may correspond to four different threshold voltages V₁, V₂, V₃, and V₄ of the memory cell.

In one example, a memory device may have a plurality of memory cells. Even in case the memory cells are substantially identical, their particular storage levels, i.e., the threshold voltage, may slightly differ among the plurality of cells. These variations or fluctuations of the individual storage levels, in particular when reading the memory cells, may be caused by small structural differences due to fabrication inaccuracies or by the influence of the temperature on the threshold voltages, for example.

FIG. 5B shows a schematic example of a distribution of the four storage levels for a plurality of memory cells. Due to the variations of the threshold voltage V_{T} over the plurality of memory cells, each storage level labeled with “11”, “01”, “00”, and “10”, in accordance with FIG. 5A, exhibits a broadening. The quantity “n” in FIGS. 5A and 5B represent the number of memory cells having a storage level at the respective threshold voltage V_{T} indicated at the abscissa of FIGS. 5A and 5B. At least as long as the areas for the individual storage levels do not overlap, the storage levels for all memory cells can be easily distinguished by comparing the respective threshold voltages with a global reference voltage, for example. Such a reference voltage may be set or defined at a value somewhere between the areas occupied be the memory cell as shown in FIG. 5B, for example.

In accordance with this description, a signal level or storage level may be understood as a range or interval around or centered to a specific value of the signal or a specific storage state. In one aspect different signal levels or storage levels are distinguishable. They may, for example, have no overlap within a group of storage sites or a set of signals.

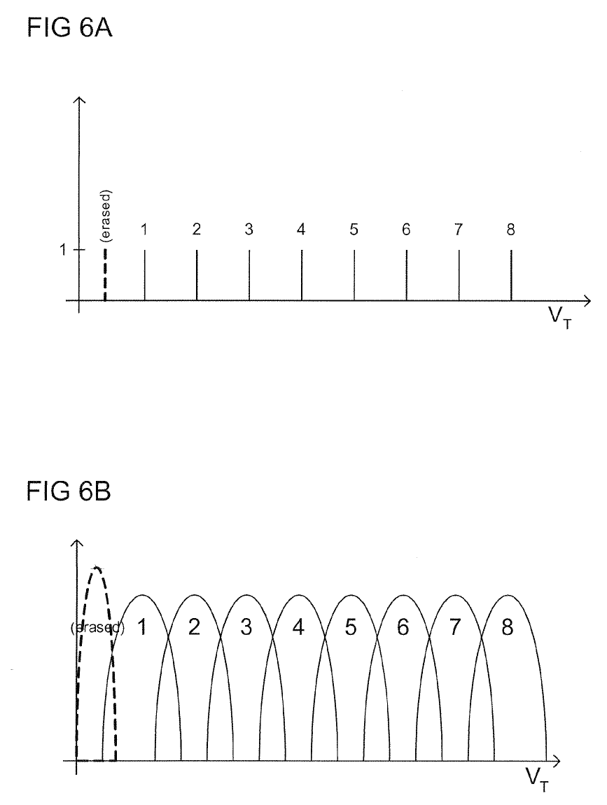

FIG. 6A shows another example of a distribution of storage states for another multi-level memory cell. According to this example, each multi-level memory cell may exhibit 8 storage levels labeled with “1” to “8” in FIGS. 6A and 6B. Each storage level corresponds to one particular threshold voltage V_{T}. In one example each memory cell may exhibit another state labeled with “erased” in FIGS. 6A and 6B, in addition to the 8 storage states. Analogous to the examples described in connection with FIGS. 3 to 5, a memory cell according to the example of FIG. 6A may also be achieved by providing a memory cell having 3 charge trapping packets each representing one bit of information, for example. Accordingly, the levels “1” to “8” could also be labeled or identified via their bit combinations, such as “111”, “011”, etc., for example. In another example, different storage states are defined by different charging of a floating gate included in the memory cell, for example.

In one aspect, a multi-level memory cell does not define an intrinsic structural quantization or definition of discrete values of a threshold voltage but it may exhibit a continuum of threshold voltages depending on a charging of a floating gate, i.e., an amount of electrical charge transferred to the floating gate, for example. In this case, the plurality of storage states may be provided by preparing the memory cell through a plurality of predefined charging conditions or predetermined writing processes, where each of the predefined conditions for writing may set the memory cell in one of a plurality of reproducible storage states.

FIG. 6B shows an example of an ensemble of memory cells similar to the memory cell the characteristic level distribution of which has been shown in FIG. 6A. Unlike the ensemble of FIG. 5B, in an ensemble according to FIG. 6B neighboring storage states exhibit an overlap, i.e., for some memory cells within the ensemble of memory cells the level k is higher than the corresponding level k+1 of other memory cells within the ensemble, for example. Accordingly, when evaluating or reading the storage states of the memory cells by comparing the threshold voltages with global reference voltages, wrong information may be read, since in the voltage region of the overlap a clear distinction between the levels is difficult. Therefore, redundancy may be introduced by means of a control bit such as a so-called zero counter, for example, for counterchecking such read errors.

In one aspect, a memory device has a data interface; at least one memory unit having a plurality of multi-level memory cells each memory cell having a plurality of storage levels; and a code converter such as an encoder/decoder component in communication with the data interface and the plurality of multi-level memory cells for converting between sets of binary signals communicated on the data interface and sets of multi-level storage signals, wherein each storage signal within a set of storage signals has a signal level that is unique within the set of storage signals.

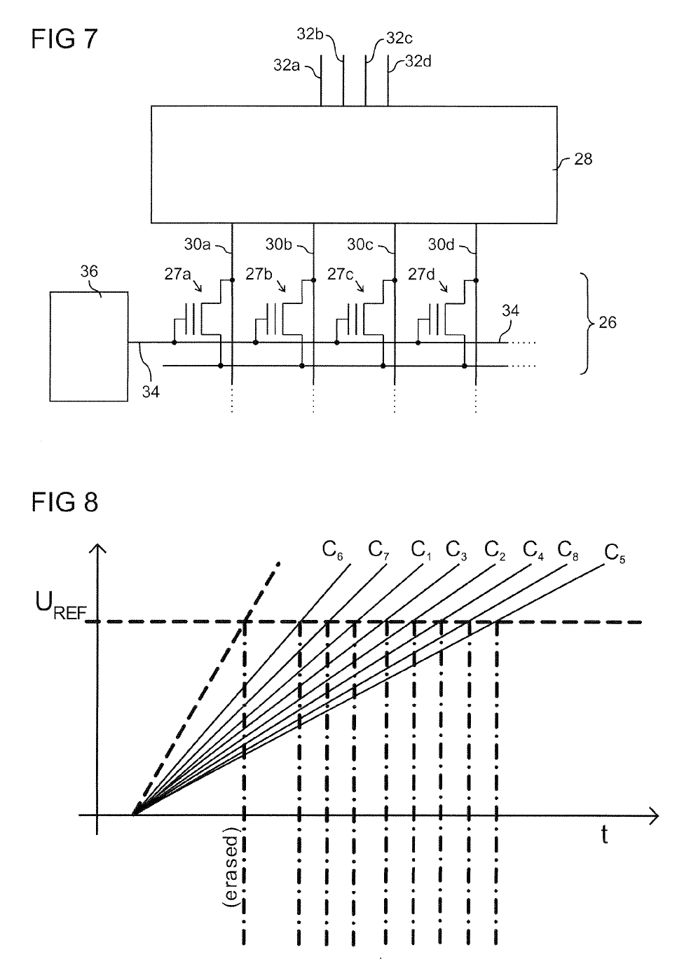

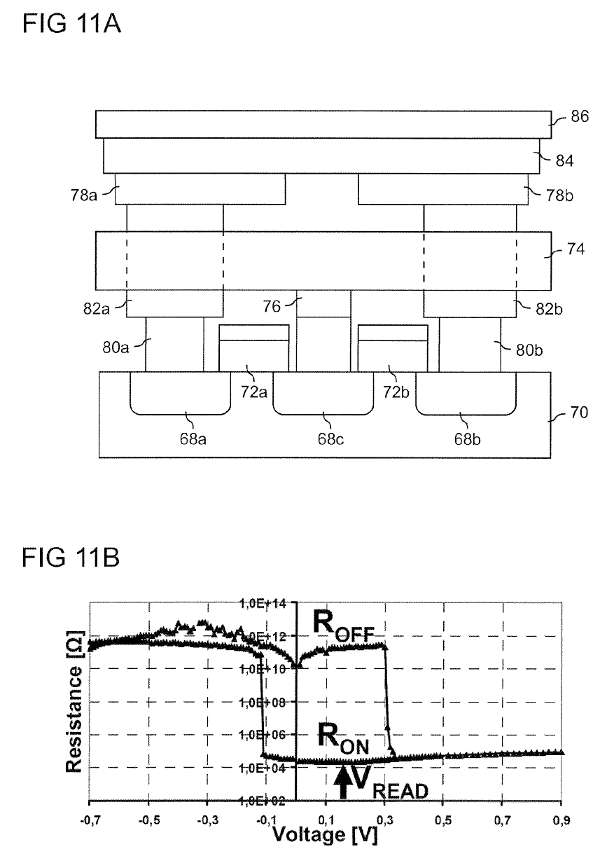

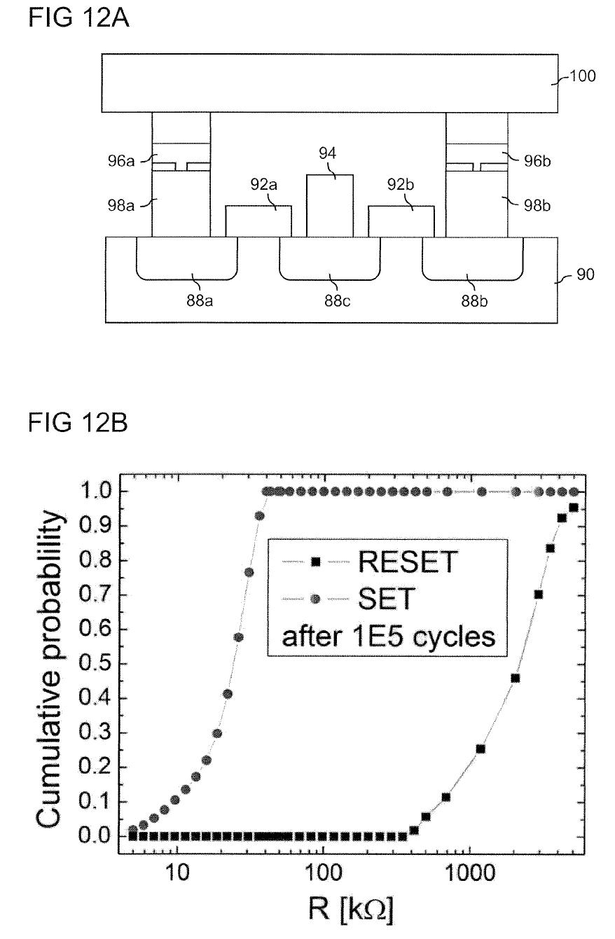

FIG. 7 shows an example of a memory device having at least one memory unit 26. The memory unit 26 has a plurality of multi-level memory cells 27a, 27b, 27c, 27d. Each of the memory cells 27a-27d communicates with a code converter component 28 via a storage signal line or bit line 30a, 30b, 30c, 30d. The signals communicated via the bit line may have multi-level signals, i.e., each of the signals may take one out of a plurality of signal levels, such as predetermined levels of electrical signals, for example. In particular, the communicated signal level may be selected or determined according to a storage state associated with the respective memory cell. Particularly, the number of possible levels of the multi-level signals may correspond to or be identical to the number of possible storage states that the respective memory cell may exhibit. In one example, the memory unit 26 is provided with at least three multi-level memory cells. In another example the memory unit 26 is provided with at least four multi-level memory cells 27a-27d, each having at least four possible storage states. The memory cells 27a-27d may, for example, be implemented as NROM memory cells 10 or as floating gate memory cells 11 described in connection with FIGS. 3A and 3B, respectively. Nevertheless, the memory device is not limited to these examples and any other types of memory cells may be applied, such as resistive, magnetic, optic or other types of memory cells. Examples of resistive memories will be described in more detail with reference to FIGS. 11 and 12 below.

In one aspect, an integrated circuit may be adapted to be programmed. According to one particular example, the memory device is adapted to store data. In particular, a method of programming an integrated circuit or storing data in an integrated circuit, such as a memory device, for example, may include identifying a group of storage sites from a plurality of storage sites. A plurality of storage levels may be selected, wherein each storage level is assignable to a storage site in the group of storage sites. From this plurality of storage levels a unique storage level may be assigned to each of the storage sites in the group of storage sites. In one particular example a method of storing data in a memory device may include providing the memory device with at least one group of storage sites, such as a memory unit 26 having a plurality of storage sites, such as multi-level memory cells 27a-27d, each memory cell 27a-27d having a plurality of storage levels or storage states. In this aspect the method may further include setting each memory cell 27a-27d within the memory unit 26 into a storage level or storage state that is unique within the memory unit 26 depending on the data to be stored, i.e., none of the other memory cells within the same memory unit 26 takes the same storage level.

In another aspect, it is not required that all storage levels or storage states are unique within a group of storage sites or within a memory unit. Instead, one or more storage levels from a selected plurality of storage levels may occur more than once within the same group of storage sites or even within each storage site. In this aspect an occurrence number may be previously defined for the one or more storage levels to define how often the respective storage level occurs within the group of storage sites, i.e., how may storage sites within the group of storage sites are set to the respective storage level. According to one example of this aspect, a method of storing data in an integrated circuit may include identifying a group of storage sites from a plurality of storage sites; selecting a plurality of storage levels, each storage level being assignable to at least one storage site in the group of storage sites; defining for each storage level from the plurality of storage levels how many storage sites in the group of storage sites the storage levels is to be assigned to, independent of the data to be stored; and assigning each storage level from the plurality of storage levels to as many storage sites in the group of storage sites as defined. The storage levels are assigned to the storage sites depending on the data to be stored. In a case where the occurrence number is 1 for all storage sites within the group of storage sites, the situation may be the same as described for unique storage levels.

In another aspect, an integrated circuit, such as the memory device is adapted for reading data stored in the integrated circuit, particularly for reading data stored in the plurality of memory cells 27a-27d. In particular, a method of reading data stored in an integrated circuit, such as a memory device, may include comparing storage levels of a plurality of storage sites, such as multi-level memory cells 27a-27d, within a group of storage sites, such as a memory unit 26, for example; and deriving the stored data from the comparison of the storage levels of the multi-level memory cells within the memory unit 26. According to this aspect, a determination or retrieval of stored information is based on a relative comparison of storage levels within the memory unit 26. Accordingly, it is not required to compare the storage levels with a global reference. In one aspect, it is not required that all storage sites within the group of storage sites, such as the memory unit, are compared with all other storage sites within the group of storage sites.

Since variations or a shift of storage levels or the scattering of storage levels in a locally small area of a memory device is often rather small as compared to the scattering of the levels across a full memory device, in one example the memory unit 26 may have memory cells within a small local area of the memory device. Accordingly, reading errors may be reduced by this method, where the comparison of storage levels is made within the memory unit 26. Accordingly, in one aspect it can be refrained from a control bit such as a zero-counter, for example.

In one aspect of a method of storing data, such as one of the above described method of storing data, setting each memory cell into a unique storage level may include establishing or defining a sequence pattern of a plurality of storage levels that are distinct from one another such that the established sequence pattern uniquely represents the data to be stored. Examples for sequences of four storage levels have been described in connection with Table 1, above. Particularly, each line in the right column of Table 1 represents one sequence pattern of storage levels. Furthermore, in one aspect the method may further include assigning to each of the plurality of memory cells within the memory unit 26 one of the plurality of storage levels in accordance with the established sequence pattern. Referring to the last line in Table 1, for example, according to the established sequence pattern of storage levels V₂-V₄-V₁-V₃ the method may assign the storage levels V₂, V₄, V₁, and V₃ to the respective memory cells C₄, C₃, C₂, and C₁.

In another aspect, the method may include establishing or defining an order or a sequence of the memory cells within the memory unit such that a resulting order of the cells uniquely represents the data to be stored. For example, the method may assign an ordinal number to each of the plurality of memory cells resulting in an ordering C₂-C₄-C₁-C₃, for example, where the established ordering uniquely represents the data to be stored. In this aspect, the method may further include setting each memory cell within the memory unit into a storage level uniquely representing the assigned ordinal number, where each storage level is unique within the memory unit. In the above mentioned example, therefore, the method may set each of four memory cells in a different storage state selected from the storage states V₁, V₂, V₃, and V₄, in accordance with the established ordering C₂-C₄-C₁-C₃. Accordingly, C₂ may be set into the storage state V₁, C₄ may be set to V₂, C₁ may be set to V₃, and C₃ may be set to V₄, which corresponds to the example discussed above in connection with the last line in Table 1.

In one example, the method may include receiving on a data bus or data interface an input set of binary signals representing data to be stored in a group of storage sites of an integrated circuit, such as data to be stored in the memory unit of the memory device. The binary signals, therefore, form a binary representation of information to be stored. According to this example, the memory device has a data interface or data bus 32 having a plurality of binary signal lines 32a, 32b, 32c, 32d in communication with the code converter component 28. The code converter component 28 may have an encoder for encoding the received binary signals to generate an output set of multi-level signals having a sequence of a plurality of storage signals each representing a signal level that is unique within the plurality of storage signals included in the set of multi-level signals such that the sequence of distinct signal levels biuniquely represents the data to be stored in the memory unit of the memory device. Encoding may be performed in accordance with the method of encoding data as described above, for example.

The code converter component 28 may communicate the multi-level signals to the bit lines 30 (illustrated as lines 30a-30d) and, thus, assign to each of the plurality of multi-level memory cells 27 (illustrated as memory cells 27a-27d) within the memory unit one of the plurality of storage signals. The method may then set each memory cell 27 into a storage level biuniquely representing the unique signal level of the storage signal assigned to the memory cell. For example, the multi-level memory cells 27 may have multi-level flash memory cells each having a plurality of possible threshold voltages, where setting each memory cell into a unique storage level may include setting a threshold voltage uniquely identifying the storage level to each of the memory cells within the memory unit.

In one particular example, receiving on the data bus 32 the input set of binary signals may include receiving on the data bus 32 a data block or sequence of binary signals representing a data word. Depending on the particular field of application, the data word may represent a standard unit or block of bits, such as binary data representing 4 bits or 8 bits or 16 bits, for example. In one example these bits may be received on the data bus serially. In another example the whole word (data word) may be received at the same time, i.e., the block of bits may be received in parallel.

In one aspect of the method of reading data each storage level taken by one of the plurality of multi-level memory cells is unique among the storage levels taken within the memory unit, and comparing storage levels of the memory cells may include determining an order of the memory cells within the memory unit depending on their relative storage levels. If the multi-level memory cells 27 have flash memory cells, for example, comparing the storage levels of the cells may include comparing threshold voltages of the flash memory cells. For example, comparing the threshold voltages of the flash memory cells may include comparing conductance values of the plurality of memory cells at a predetermined control gate voltage.

As already indicated above, it is, however, not necessary that each storage site within a group of storage sites, such as a memory unit, is set to a unique storage level. When referring to Table 2, for example, a group of storage sites may have 6 storage sites, such as memory cells C₆, C₅, C₄, C₃, C₂, and C₁, each being set to one out of three storage levels V₁, V₂, V₃. In the example of Table 2, each storage level has an occurrence number of 2. Also in this example, comparing storage levels of the memory cells may include determining an order of the memory cells within the memory unit depending on their relative storage levels. In particular, although two memory cells, such as memory cells C₆ and C₄, for example, may be set to the same storage level V₁, for example, a comparison of these two memory cells may exhibit a small difference in the actual physical quantity, such as the threshold voltage in case of flash memory cells, for example. This small difference may result from small fluctuations and imperfections in the fabrication of the integrated circuit. This difference may even change with time such that the relative position of these cells in a determined order of the cell may change with time. Nevertheless, since either of the orders C₆-C₄-C₁-C₂-C₃-C₅ and C₄-C₆-C₁-C₂-C₃-C₅ corresponds to the same bit sequence 0-0-0-1-1-1, as can be seen from Table 2, such fluctuation of the storage state does not affect the stored data in this example.

FIG. 8 demonstrates one example of a process of reading data from a memory unit having 8 multi-level memory cells. According to this example, comparing conductance values of the plurality of memory cells may include applying a read voltage to the plurality of memory cells and comparing a current through the cells. In particular, comparing the current through the cells may include charging sense capacitors of equal capacity by applying the cell currents to the capacitors and determining the chronological order of capacitor voltages dropping at the sense capacitors to arrive at, or to match, or to cross a common reference voltage level U_{REF}. FIG. 8 shows the increase of the capacitor voltages for the 8 memory cells C₁ to C₈ with time t. The slope of the solid lines is a measure of the cell current or conductance and, therefore, represents a measure of the threshold voltage and, thus, the storage level or storage state. C₆ is the first, C₇ the second cell, etc., to match the reference voltage U_{REF}. Accordingly, the determined order C₆-C₇-C₁- . . . -C₅ represents the data stored in the memory unit. This data or information is retrieved by comparison of the cell states within the memory unit. No state of an external or global reference cell is required in this aspect.

In one aspect of an integrated circuit, each storage site within at least one group or set of storage sites has a transistor having a gate contact, wherein the gate contacts within the group of storage sites are electrically connected to a common word line. In a particular example of a memory unit according to this aspect, each multi-level memory cell within the memory unit has a storage transistor and/or a select transistor having a gate contact, such as the control gate 14, wherein the gate contacts within the memory unit are electrically connected to a common word line 34.

In one aspect the memory device has a plurality of memory units, wherein each memory unit has a plurality of multi-level memory cells each memory cell having a plurality of storage levels, particularly more than two storage levels. The number of possible storage levels for each of the memory cells within one memory unit may correspond to or may be not smaller than the number of memory cells within the memory unit. In one example, a memory device has an address interface 36 for receiving address data selecting the memory unit 26 to communicate multi-level storage signals with the code converter 28 by selection of the word line 34, for example.

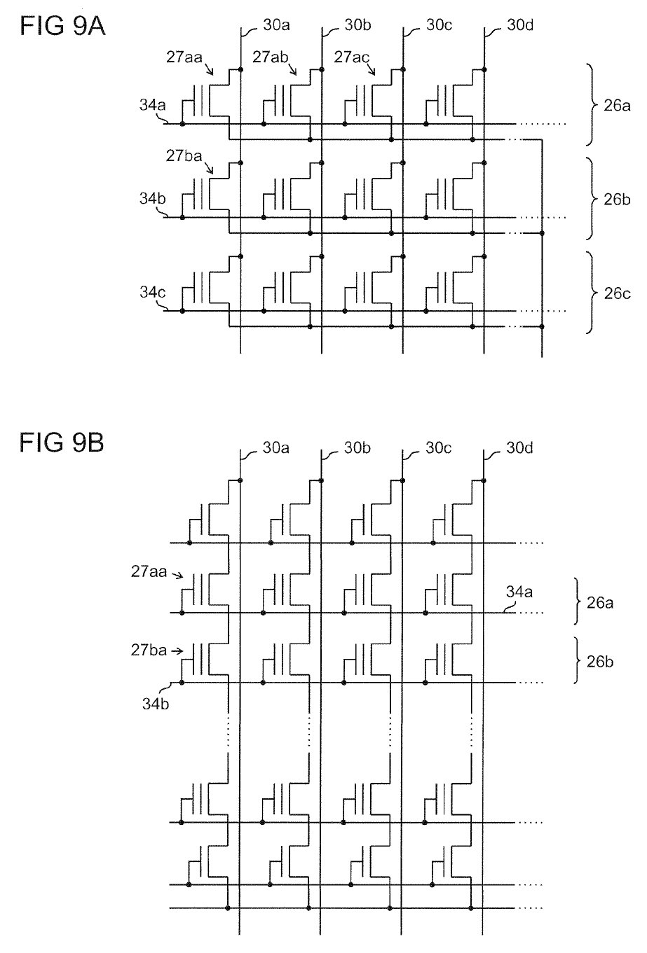

According to the example shown in FIG. 9A and FIG. 9B, in one aspect a plurality of multi-level memory cells 27aa, 27ab, 27ba, etc. is arranged in at least one cell array having rows of memory cells that are electrically connected to a common word-line 34a, 34b, etc. for each row, and columns of memory cells that are electrically connected to a common bit-line 30a, 30b, etc. for each column, wherein each row may have or represent one memory unit 26. In one example the at least one cell array has a NOR architecture as shown in FIG. 9A. In another example, the at least one cell array has a NAND architecture as shown in FIG. 9B. Nevertheless, the memory device is not limited to these circuit architectures.

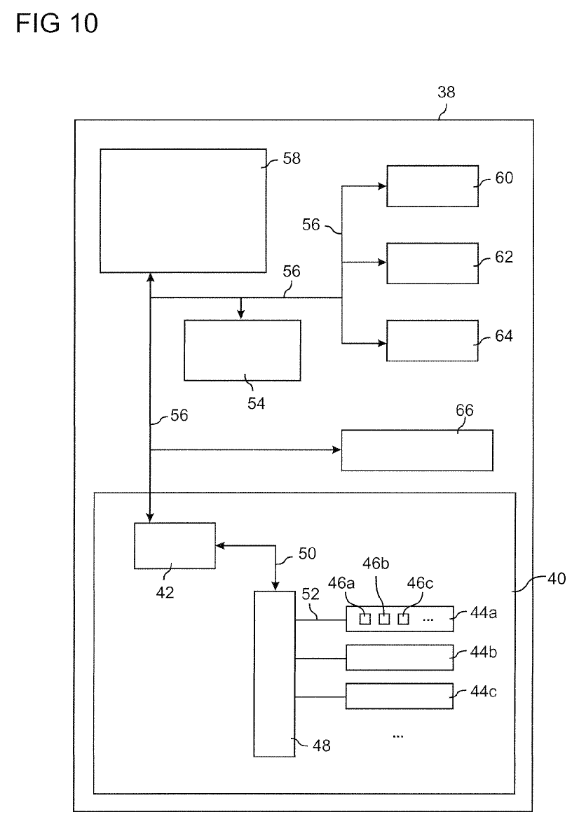

In yet another aspect shown in FIG. 10, an electronic device 38 such as a computer (e.g., a mobile computer), a mobile phone, a pocket PC, a smart phone, a PDA, for example, or any kind of consumer electronic device, such as a TV, a radio, or any house hold electronic device, for example, or any kind of storage device, such as a chip card or memory card, for example, has one or more storage components 40 having a data interface 42; one or more memory units 44a, 44b, 44c or groups of storage sites, wherein each memory unit 44 has a plurality of multi-level memory cells 46a, 46b, 46c each memory cell 46 having a plurality of discriminable storage levels. In one example, more than two storage levels or more than three storage levels or even more than four storage levels may be provided for each of the multi-level memory cells 46. In one example, for each group of storage sites the number of storage levels of the multi-level storage sites included in the group of storage sites may correspond to the number of storage sites within the group of storage sites.

In one example, the storage component 40 further has a code converter 48, such as an encoder/decoder component, in communication with the data interface 42 and the plurality of multi-level memory cells 46 for converting between sets of binary signals 50 communicated on the data interface 42 and sets of multi-level storage signals 52, wherein each storage signal within a set 52 of storage signals has a signal level that is unique within the set 52 of storage signals. In one example, the code converter 48 may have a code converter component 28 and/or the data interface may have an address interface 36 in accordance with the example described in connection with FIG. 7 above.

In one example, one or more of the above described multi-level memory cells may be applied as the multi-level memory cells 46 of the memory units 44. Moreover, the memory units 44 may be structured in accordance with one or more of the memory units 26 described in connection with FIGS. 7 or 9, for example. Nevertheless, alternatively or additionally other memory cells or other memory unit architectures may be applied. In one example, reading and/or writing of data from and/or into the memory units 44 or memory cells 46 may be performed in accordance with one or more of the above described examples, although the electronic device is not limited to these methods.

In one example, for each memory unit 44 the number of distinguishable or discriminable or separable storage levels of the multi-level memory cells 46 included in the memory unit 44 corresponds to the number of memory cells 46 within the memory unit 44. In one example, an electronic device has a data flash memory that has one or more storage components 40. In another example, an electronic device has a code flash memory that has one or more storage components 40.

In one example, the electronic device 38 may have a processing unit 54 and a system bus 56 that couples various system components including the storage component 40 to the processing unit 54. Particularly, the data interface 42 may be in communication with the system bus 56 of the electronic device 38. The processing unit 54 may perform arithmetic, logic and/or control operations by accessing the storage component 40, for example. The storage component 40 may store information and/or instructions for use in combination with the processing unit 54. The storage component 40 may have volatile and/or non-volatile memory cells 46. The storage component 40 may be implemented as a random access memory (RAM) or a read only memory (ROM), for example. In one example, a basic input/output system (BIOS) storing the basic routines that helps to transfer information between elements within the electronic device 38, such as during start-up, may be stored in the storage component 40. The system bus 56 may be any of several types of bus structures including a memory bus or memory controller, a peripheral bus, and a local bus using any of a variety of bus architectures.

The electronic device 38 may further have a video input and/or output device 58, such as a display interface or a display device or a camera, connected to the system bus 56, for example. Alternatively or in addition to the video device 58 the electronic device 38 may have an audio device 60 for inputting and/or outputting acoustic signals, such as a speaker and/or a microphone, for example. Moreover, in one example, the electronic device 38 may have an input interface 62, such as input keys and/or an interface for connecting a keyboard, a joystick or a mouse, for example. In yet another example, the electronic device may have a network interface 64 for connecting the electronic device to a wired and/or a wireless network. Furthermore, one or more additional memory components 66 may be included in the electronic device.

In one aspect, the storage component 40 is implemented as a data memory for storing computer readable instructions, data structures, program modules and/or other data for the operation of the electronic device 38. In another aspect, the storage component 40 may be implemented as a graphical memory or an input/output buffer. In one aspect the storage component 40 is fixedly connected to the electronic device 38. In another aspect, the storage component 40 is implemented as a removable component, such as a memory card or chip card, for example.

Further features of a memory device are apparent from Table 3. Table 3 list the amount of information that can be stored in a memory device as described above in comparison with a memory device according to the Quad-Technology having two bit per cell.

TABLE 3
Comparison of storage schemes

| | Quad-Technology | | | |
|---|---|---|---|---|
| | (2 bit per cell) | | coding of this description | |
| number of | number of | number of | number of | number of |
| cells | possible states | bits | possible states | bits |
| 2 | 16 | 4 | 3 | 1 |
| 3 | 64 | 6 | 7 | 2 |
| 4 | 256 | 8 | 25 | 4 |
| 5 | 1024 | 10 | 121 | 6 |
| 6 | 4096 | 12 | 721 | 9 |
| 7 | 16384 | 14 | 5041 | 12 |
| 8 | 65536 | 16 | 40321 | 15 |
| 9 | 262144 | 18 | 362881 | 18 |
| 10 | 1048576 | 20 | 3628801 | 21 |

The amount of information that can be stored within a memory unit depends on the number of cells within the memory unit (left column). With two cells, in the Quad-Technology the number of possible states that can be taken is 16, i.e., the amount of information contained in 4 bit can be stored, for example. For a memory device described above, the number of possible storage states is 2 and, including an “erased” state, the total number of distinguishable states is 3. With 10 cells within the memory unit, on the other hand, the number of possible states and, therefore, the amount of information that can be stored is greater in a memory device described above as compared to the Quad-Technology.

Although some of the described examples are directed to flash type memory cells, particularly to charge trapping memory cells and floating gate memory cells, it will be appreciated that the described methods of storing, reading, encoding or decoding information and the described memory units and devices are not limited to these types of memory cells. Other memory cells, such as other flash memory cells or other non-volatile memory cell types may be applied.

According to one particular example, resistive memory cells, such as conductive bridging (CB) memories or phase change (PC) memories may be applied instead of or in addition to the above described memory cells, such as flash type memory cells. In this examples, a cell resistance may be applied as a signal level or storage level, for example.

FIG. 11A shows a cross section of a conductive bridging RAM (CBRAM), according to one example. In this example, n⁺-type contact regions 68a, 68b, 68c are arranged in a p-type semiconductor substrate 70. The contact regions 68a, 68b, 68c serve as source/drain regions of field effect transistors, the channel regions of which are controlled by gates formed by or connected to wordlines 72a and 72b, respectively. One of the shown contact regions 68c is electrically connected to a bitline 74 via a bitline contact 76. Other contact regions 68a, 68b of the transistors are electrically connected to storage contacts 78a, 78b via contact nodes 80a, 80b and cell contacts 82a, 82b, for example. Each storage contact 78a, 78b is arranged at a storage medium 84, which in the shown example is provided as a common chalcogenide layer 84. Each storage contact 78a, 78b acts as a first electrode of a conductive bridging cell, where the second electrode is formed by an Ag-rich plate electrode 86. In this example, the plate electrode 86 may form a reactive electrode while the storage contacts 78a, 78b may form an inert electrode of the CB cells.

Upon application of an appropriate electric SET or RESET pulse between the plate electrode 86 and one or more of the storage contacts 78a, 78b, an electrically conductive bridge between the respective electrodes may be at least partly formed or broken up, respectively, within the storage medium 84, thereby programming or writing the storage cell. Depending on the resulting electric conductance or resistance of the respective storage cell, one of a plurality of storage states or storage levels may be achieved. In the example of FIG. 11B, two distinguishable resistive storage levels are shown, namely a high resistive OFF-state R_{OFF} and a low resistive ON-state R_{ON}. When applying a read voltage V_{READ} these states may be distinguished based on the resulting current through the cell. In one aspect this resulting current may form a storage signal representing one out of a plurality of possible signal levels. In particular, depending on the state of cell the resistance R_{ON} and/or the resistance R_{OFF} may take a different level, such that the respective storage cell may form a multi-level storage cell.

According to another example shown in FIG. 12A, a phase change (PC) memory may be provided. In this example, n⁺-type contact regions 88a, 88b, 88c may be arranged in a p-type semiconductor substrate 90. Similar to the previous example, the contact regions 88a, 88b, 88c may serve as source/drain regions of field effect transistors, the channel regions of which are controlled by gates formed by or connected to wordlines 92a and 92b, respectively. One of the shown contact regions 88c is electrically connected to a common source line 94. Other contact regions 88a, 88b of the transistors are electrically connected to storage regions 96a, 96b by means of drain via contacts 98a, 98b, for example. On the other hand, the storage region 96a, 96b is electrically connected to a bitline 100. In this example, the storage regions 96a, 96b may be formed by a phase change material, where a change of a phase of the material may be achieved by applying an appropriate electric or thermal SET or RESET pulse. This phase change may go along with a change in the electric resistance of the storage medium 96a, 96b. The resulting resistance may represent one out a plurality of storage levels of the respective restive storage cell. FIG. 12B shows the cumulative resistance distribution for an array of cells after 10⁵ SET-RESET cycles, according to one example.

In other examples, the methods, memory units and devices are also not limited to non-volatile memory cells. Instead, also any type of volatile memory cell may be applied.

A number of examples and implementations have been described. Other examples and implementations may, in particular, have one or more of the above features. Nevertheless, it will be understood that various modifications may be made. Particularly, multi-level signals are not limited to electrical signals. Any other physical characteristics, such as magnetic, optical or even mechanical properties, or a period of time, i.e., not only a level of a signal but also a duration of a signal may be applied as multi-level signals when encoding, decoding, reading or writing data, for example. Moreover the memory cells are not limited to the examples described in detail above. Also other types of memory cell concepts, such as memory cells having transistors and capacitors may be applied. Data may be read from the cells or written into the cells electrically, magnetically, optically or by any other technique appropriate for the particularly applied type of memory cell. It will also be appreciated that memory units are not necessarily arranged in rows or columns of a cell array. In other examples, not explicitly shown or described in the figures, any other arrangement of memory cells within a memory unit may be applied. Accordingly, other implementations are within the scope of the following claims.

What is claimed is:

1. A method of storing data in an integrated circuit, the method comprising:
identifying a group of storage sites from a plurality of storage sites;
selecting a plurality of storage levels, each storage level being assignable to a storage site in the group of storage sites; and
assigning a unique storage level to each of the storage sites in the group of storage sites, each unique storage level assigned from the plurality of storage levels.

2. The method of claim 1, wherein selecting a plurality of storage levels comprises selecting storage levels that are assignable to a plurality of storage sites in the group of storage sites.

3. The method of claim 1, comprising receiving input signals representing data to be stored in the integrated circuit, wherein assigning a unique storage level to each of the storage sites comprises assigning to each of the storage sites in the group of storage sites a storage level from the plurality of storage levels depending on the received input signals in such a way that for each storage site the assigned storage level is unique within the group of storage sites independent of the received input signals.

4. The method of claim 3, wherein receiving input signals comprises receiving a number n of binary signals, wherein identifying a group of storage sites comprises identifying a group of storage sites comprising a number k of storage sites such that the number k is the smallest integer number the factorial k! of which is not smaller than 2ⁿ.

5. The method of claim 1, wherein identifying a group of storage sites comprises identifying a group of storage sites comprising at least three storage sites and wherein selecting a plurality of storage levels comprises selecting at least three discriminable storage levels.

6. The method of claim 1, wherein assigning a unique storage level to each of the storage sites comprises:
establishing a sequence pattern of the selected plurality of storage levels such that the established sequence pattern uniquely represents the data to be stored; and
assigning to each of the storage sites in the group of storage sites one of the plurality of storage levels in accordance with the established sequence pattern.

7. The method of claim 1, wherein the group of storage sites comprises a group of flash memory cells, each flash memory cell having a plurality of possible threshold voltages, and wherein assigning a unique storage level to each of the storage sites comprises setting a unique threshold voltage for each of the flash memory cells within the group of flash memory cells to a value representing the unique storage level.

8. The method of claim 1, wherein the group of storage sites comprises a group of resistive memory cells, each resistive memory cell having a plurality of possible values of electrical resistance, and wherein assigning a unique storage level to each of the storage sites comprises setting a value of the electrical resistance for each of the resistive memory cells within the group of resistive memory cells to a value representing the unique storage level.

9. A method of storing data in an integrated circuit, the method comprising:
identifying a group of storage sites from a plurality of storage sites;
selecting a plurality of storage levels, each storage level being assignable to at least one storage site in the group of storage sites;
defining for each storage level from the plurality of storage levels how many storage sites in the group of storage sites the storage level is to be assigned to; and
assigning each storage level from the plurality of storage levels to as many storage sites in the group of storage sites as defined.

10. The method of claim 9, wherein occurrence numbers for all storage levels from the plurality of storage levels are the same.

11. An integrated circuit comprising
a data interface;
a group of storage sites having a plurality of storage levels, each storage level being assignable to a storage site in the group of storage sites; and
a code converter in communication with the data interface and the group of storage sites for converting between a set of interface signals communicated on the data interface and a group of storage signals communicated with the group of storage sites such that to each storage site from the group of storage sites a storage signal from the group of storage signals is assigned that represents a unique storage level from the plurality of storage levels.

12. The integrated circuit of claim 11, wherein the group of storage sites comprises a number of k storage sites each having a number of k storage levels assignable to the storage site, and wherein k is at least 4.

13. The integrated circuit of claim 11, comprising a plurality of groups of storage sites with the same number of storage sites comprised in each of the plurality of groups of storage sites.

14. The integrated circuit of claim 11, wherein the group of storage sites comprises non-volatile memory cells.

15. The integrated circuit of claim 14, wherein the group of storage sites comprises flash-memory cells and wherein the plurality of storage levels comprises threshold voltages each of which being assignable to a flash-memory cell in the group of storage sites.

16. The integrated circuit of claim 14, wherein the group of storage sites comprises resistive memory cells and wherein the plurality of storage levels comprises values of electrical resistance each of which being assignable to a resistive memory cell in the group of storage sites.
